(19) United States
(12) Patent Application Publication
(10) Pub. No.: US 2008/0102561 A1
(43) Pub. Date: May 1, 2008

(54) METHODS OF MANUFACTURING PRINTED CIRCUIT BOARD ASSEMBLY

(75) Inventors: YASUNORI GOTO, SAGAMIHARA-SHI (JP); JIRO TAKEDA, TOKYO (JP); TSUTOMU MASAKI, SAGAMIHARA-SHI (JP)

Correspondence Address: SCHLUMBERGER K.K., 2-2-1 FUCHINOBE, SAGAMIHARA-SHI, KANAGAWA-KEN, 229-0006, omitted

(73) Assignee: SCHLUMBERGER TECHNOLOGY CORPORATION, Sugar Land, TX (US)

(21) Appl. No.: 11/552,987

(22) Filed: Oct. 26, 2006

(51) Int. Cl. H01L 21/00

(52) U.S. Cl. 438/106

(57) ABSTRACT

Methods of manufacturing printed circuit board assemblies include placing a semiconductor chip having a plurality of lead terminals on a board formed with a plurality of solder lands at its surface such that each of the plurality of lead terminals is in touch with a corresponding one of the solder lands; supplying a solder material on the plurality of lead terminal s and the plurality of solder lands; supplying a flux including mono salt of adipic acid and alkyl secondary amine; and locally heating the plurality of lead terminals such that the solder material and the flux are melted to join together the lead terminals and the solder lands.

### TECHNICAL FIELD

The present invention relates generally to methods of manufacturing a printed circuit board assembly including a semiconductor chip mounted on a board. More particularly, the present invention relates to manufacturing printed circuit boards suitable for high temperature and high vibration environments, such as typically found downhole in oil wells.

### BACKGROUND

It has been found that short circuit board life has been a problem in integrated circuits (IC) using fine pitch surface-mounted technology (hereinafter referred to as “fine pitch SMT ICs”), where the distance between each IC lead terminal is less than about 0.65 mm. The problem has been particularly evident when the fine pitch SMC ICs are used in a downhole logging tool, i.e., the circuit boards are subjected to severe environments, such as high temperature of about 150 degrees centigrade or more, and/or mechanical shocks and vibration such as experienced by tools during logging operations. In such cases, the operational life of the fine pitch SMT ICs is considerably shortened, and use of the circuit boards is problematic.

### SUMMARY

The present specification provides some embodiments directed towards improving, or at least reducing, the effects of one or more of the above-identified problems. In one of many possible embodiments, an object is to extend the life of semiconductors such as SMT ICs, especially when the printed circuit board assemblies are used in high temperature environments. The present inventors recognized the reason for a short circuit board life of fine pitch SMT ICs as being due to electrical disconnection problems between the IC lead terminals and the solder pads of the printed circuit boards. The present inventors further recognized that growth of an inter-metallic layer may reduce mechanical strength of the solder joints between the IC lead terminals and the solder pads of the printed circuit boards. In this, at the tin-copper interface between the copper IC lead terminals and the tin solder pads, copper diffuses into the tin layer to develop Kirkendall voids at the interface. As a consequence, mechanical strength of the solder joints is reduced. Such growth of an inter-metallic layer causes less failure in SMT ICs having relatively larger IC lead terminals, or in SMT ICs having leads that are made of materials other than copper based materials.

One aspect of methods of manufacturing a printed circuit board assembly disclosed herein provides placing a semiconductor chip having a plurality of lead terminals on a board formed with a plurality of solder lands at its surface such that each of the plurality of lead terminals is in touch with a corresponding one of the plurality of solder lands; supplying a flux including mono salt of adipic acid and alkyl secondary amine; supplying a solder material; and locally heating the plurality of lead terminals to melt the solder material and the flux so that the plurality of lead terminals are joined with the plurality of solder lands.

Presence of the flux during the soldering process keeps the wettability of the solder material, even at high soldering temperatures, such as 220 degrees centigrade or more, and an improved back fillet at the solder joint can be obtained. Therefore, mechanical strength of the joints is strengthened.

In addition, by local heating mechanical stresses on the printed circuit board assembly due to heat can be reduced to improve reliability of the manufactured boards.

The alkyl secondary amine of the flux may be diethyl amine. Thus, the flux may be mono salt of adipic acid and diethyl amine having the general formula of HOOC—(CH₂)₄—COO⁻N⁺—(CH₂CH₃)₂ (hereinafter referred to as “ADA flux”). The present inventors discovered that ADA flux reduces overgrowth of the inter-metallic layer, which causes Kirkendall voids during use of the circuit boards.

In some embodiments, after the local heating, an under-fill material may be supplied between the board and the semiconductor chip to fill a gap therebetween.

The inventors recognized that mechanical strength of the printed circuit board assembly can be increased by introducing the under-fill material between the board and the semiconductor chip thereby compensating for some degradation of the solder joint during use of the circuit boards.

In some embodiments, a printed circuit board assembly is manufactured by the steps comprising: placing a semiconductor chip having a plurality of lead terminals on a board formed with a plurality of solder lands at its surface such that each of the plurality of lead terminals is in touch with a corresponding one of the plurality of solder lands; supplying a solder material on the plurality of lead terminals and the plurality of solder lands; and locally heating the plurality of lead terminals to melt the solder material, wherein the heating is conducted while supplying an inert gas to the surface of the solder material.

In other embodiments herein, the local heating may be conducted under an inert gas environment such as nitrogen, argon, or a similar purged condition. The inventors recognized that by soldering under such conditions oxidization, which reduces the wettability of the solder material under the lead terminals of the semiconductor chip, can be substantially prevented even at high soldering temperatures, and an improved back fillet may be obtained at the solder joints. As a consequence, mechanical strength of the solder joints is strengthened.

Some embodiments may further include supplying, after the local heating, an under-fill material between the board and the semiconductor chip to fill a gap therebetween. As described before, the inventors recognized that mechanical strength of the printed circuit board assembly is increased by the under-fill material between the board and the semiconductor chip thereby avoiding failure even if there is some subsequent degradation of the solder joints.

Some embodiments herein contemplate applications of the claimed methods to SMT ICs where the gap between each IC lead terminal is more than 0.65 mm.

Additional advantages and novel features of the invention will be set forth in the description which follows or may be learned by those skilled in the art through reading these materials or practicing the invention. The advantages of the invention may be achieved through the means recited in the attached claims.

### BRIEF DESCRIPTION OF THE DRAWINGS

The accompanying drawings illustrate embodiments of the present invention and are a part of the specification. Together with the following description, the drawings demonstrate and explain the principles of the present invention.

FIGS. 1A and 1B are cross-sectional views of one exemplary printed circuit board assembly according to the present invention including a semiconductor chip mounted on a board with an under-fill material filling the gap between the semiconductor chip and the board.

FIG. 2 is a plan view of an exemplary printed circuit board assembly including a semiconductor chip having a plurality of fine pitch lead terminals mounted on aboard.

FIG. 3 is a flowchart of one method of manufacturing a printed circuit board assembly according to the present invention.

FIG. 4 is a cross-sectional view depicting the soldering point of a lead terminal of the semiconductor chip and a solder land of the board according to the present invention.

FIGS. 5A and 5B are cross-sectional views of one exemplary printed circuit board assembly according to the present invention including a semiconductor chip mounted on a board without under-fill material.

FIG. 6 is a flowchart of another embodiment of a method of manufacturing a printed circuit board assembly according to the present invention.

FIG. 7 is a chart showing the manufacturing conditions for test printed circuit board assemblies and the test results for the boards.

Throughout the drawings, identical reference numbers and descriptions indicate similar, but not necessarily identical elements. While the invention is susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the scope of the invention as defined by the appended claims.

### DETAILED DESCRIPTION

Illustrative embodiments and aspects of the invention are described below. It will of course be appreciated that in the development of any such actual embodiment, numerous implementation-specific decisions must be made to achieve the developers' specific goals, such as compliance with system-related and business-related constraints, that will vary from one implementation to another. Moreover, it will be appreciated that such a development effort might be complex and time-consuming, but would nevertheless be a routine undertaking for those of ordinary skill in the art having the benefit of this disclosure.

Reference throughout the specification to “one embodiment” or “an embodiment” or “some embodiments” means that a particular feature, structure, or characteristic described in connection with the embodiment is included in at least one embodiment of the present invention. Thus, the appearance of the phrases “in one embodiment” or “in an embodiment” or “in some embodiments” in various places throughout the specification are not necessarily all referring to the same embodiment. Furthermore, the particular features, structures, or characteristics may be combined in any suitable manner in one or more embodiments.

Moreover, inventive aspects lie in less than all features of a single disclosed embodiment Thus, the claims following the Detailed Description are hereby expressly incorporated into this Detailed Description, with each claim standing on its own as a separate embodiment of this invention.

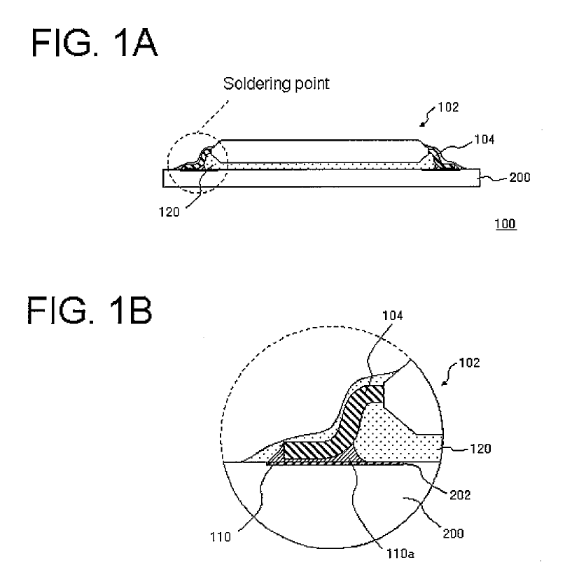

FIGS. 1A and 1B are cross-sectional views of one embodiment of a printed circuit board assembly according to the present invention. FIG. 1B is an enlarged cross-sectional view of the soldering point of the printed circuit board assembly shown in FIG. 1A.

The printed circuit board assembly 100 includes a semiconductor chip 102 having a plurality of lead terminals 104 mounted on a board 200 formed with a plurality of solder lands 202 at its surface. Each of the lead terminals 104 of the semiconductor chip 102 is electrically connected with a corresponding solder land 202 of the board 200 via a solder material 110. The printed circuit board assembly 100 includes an under-fill material 120 that fills the gap between the semiconductor chip 102 and the board 200.

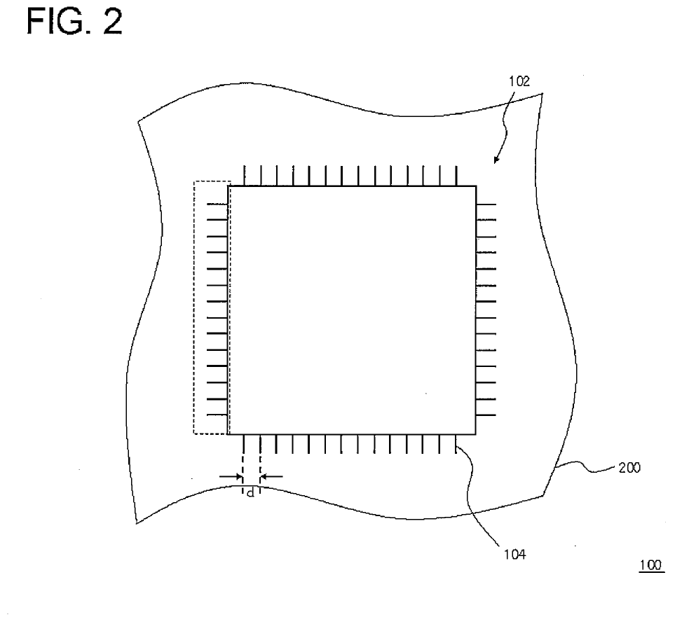

In one aspect of the disclosure herein, the printed circuit board assembly 100 may be a fine pitch SMT IC. FIG. 2 is a plan view of the printed circuit board assembly 100 including the semiconductor chip 102 having a plurality of fine pitch lead terminals 104. In one embodiment, the distance “d” between adjacent lead terminals 104 maybe equal to or less than 0.65 mm.

The printed circuit board assembly 100, according to some aspects of the present invention, may be used in a downhole logging tool such that the printed circuit board assembly 100 is used in a high temperature environment in excess of 100 degrees centigrade, for example, from about 150 to about 175 degrees centigrade or more.

The semiconductor chip 102 may be a Thin Quad Flat Package (TQFP), Plastic Quad Flat Package (PQFP), and the like. The lead terminals of the semiconductor chip 102 may be formed of copper or copper alloy For example, the lead terminals 104 of the semiconductor chip 102 may be CDA725 (Cu—Ni—Sn). The board 200 may be a printed circuit board. The solder lands 202 of the board 200 may be a solder pad, such as a tin solder pad and the like.

When the lead terminals 104 include copper and the solder lands 202 include tin, an inter-metallic layer is formed at the tin-copper interface. Since copper diffuses into the tin layer, after hundreds of heat cycles, Kirkendall voids are formed in the tin-copper interface. These voids reduce mechanical strength of the solder joints.

In order to extend the life of the printed circuit board assembly 100 under high temperature conditions (for example, 150 degrees centigrade or more), the following two approaches may be used. In one aspect of the present disclosure, damage to the printed circuit board assembly 100 may be minimized during the assembly process, which affects its life at high temperatures. In another aspect, mechanical strength of the joints between the board 200 and the semiconductor chip 102 may be strengthened against exposure to repeated heat cycles and mechanical shocks.

As certain embodiments of the printed circuit board assembly 100 of the present invention are intended for use in high temperature environments, solder material 110 having a higher melting point than the high temperature environment may be used for connecting the lead terminals 104 of the semiconductor chip 102 with the solder pads 202 of the board 200. The one aspect, the solder material 110 may have its melting point equal to or higher than about 200 degrees centigrade.

In addition, in order to achieve improved soldering joints high temperature is applied to the solder material 110 when joining the lead terminals 104 with the solder lands 202. The soldering temperature is normally 20 to 50 degrees centigrade higher than the melting point of the solder material 110. Such temperatures during soldering may cause damage to the semiconductor chip 102. For example, when the semiconductor chip 102 is exposed to such high soldering temperatures, cracks may be generated in the material encapsulating the die included in the semiconductor chip 102, or delamination may occur between the encapsulating material and the die. Therefore, in one aspect of the present invention, the solder material 110 is locally heated such that the heat does not affect the semiconductor chip 102.

In another aspect the soldering is performed under specified conditions so that oxidization of the solder material 110 is prevented during the local heating process. As a consequence wettability i.e., the ability of the solder material 110 to flow and to settle smoothly and uniformly around and under the lead terminals 104 of the semiconductor chip 102 can be maintained, and an effective and desirable back fillet 110a maybe obtained at the solder joints (note FIG. 1B).

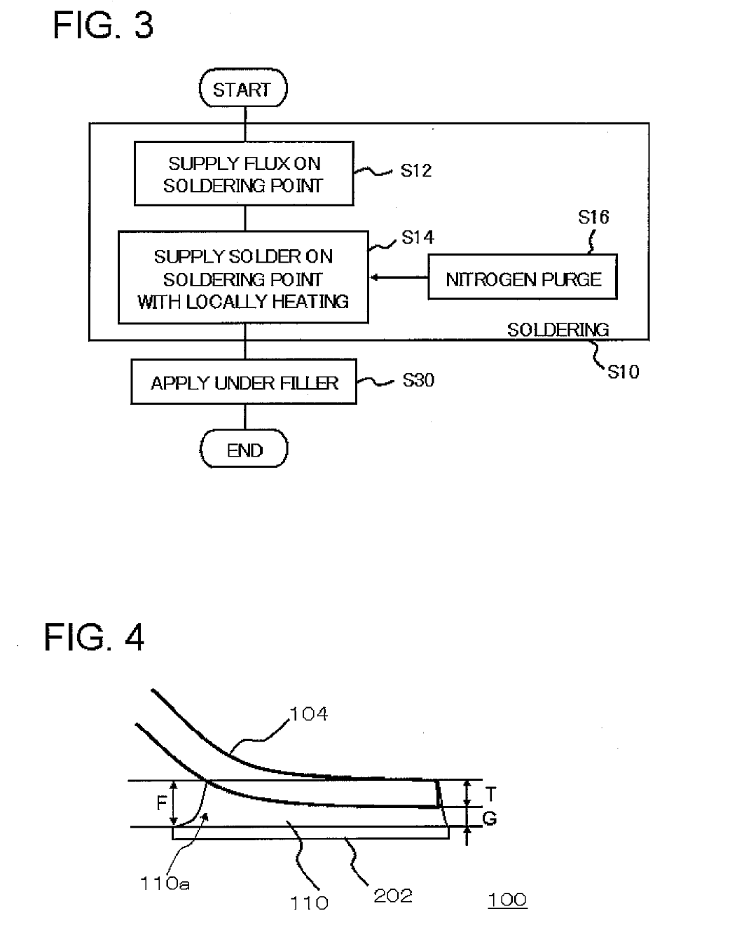

FIG. 3 is a flowchart showing one embodiment of a method of manufacturing the printed circuit board assembly 100 including soldering the semiconductor chip 102 with the board 200.

Before the soldering process (Step S10), the semiconductor chip 102 is placed on the board 200 such that each lead terminal 104 of the semiconductor chip 102 is in contact with a solder land 202.

In Step s12, a flux is supplied at the soldering point between the plurality of lead terminals 104 and the plurality of solder lands 202.

According to one embodiment, the flux may be mono salt of adipic acid and secondary amine. The secondary amine may be secondary alkyl amine of the general formula R—NH—R′, wherein R and R′ are each C₁-C₆ alkyl. The secondary amine may be secondary alkyl amine having such as dimethyl amine, diethyl amine, dipropyl amine, dibutyl amine, dipentyl amine, dihexyl amine, disopropyl amine, methylethyl amine, methylpropyl amine, ethylpropyl amine, ethylbutyl amine, and the like. Based on experimentation by the inventors, the following examples of suitable flux compositions are provided.

### EXAMPLE 1

Polypele resin (Polymeric wood rosin) 30 wt %

Gulutaric acid mono diethyl amine salt 5 wt %

The above are thoroughly mixed at 130 degrees centigrade and then cooled to room temperature. Example 1 may be used as a solid flux or an additive flux to a solder paste.

### EXAMPLE 2

Polypele resin (Polymeric wood rosin) 20 wt %

Rosin modified phenolic resin 10 wt %

Adipic acid mono diethyl amine salt 7 wt %

The above are dissolved in isopropyl alcohol in the concentration of about 10-30 wt %. Example 2 may be used as a liquid flux.

### EXAMPLE 3

Modified mareic resin 40 wt %

Modified phenolic resin 20 wt %

Gulutaric acid mono diethyl amine salt 7 wt %

Adipic acid mono diethyl amine salt 15 wt %

The above are thoroughly mixed at 130 degrees centigrade and then cooled to room temperature. Example 3 maybe used as a solid flux or an additive flux to a solder paste.

### EXAMPLE 4

Modified phenolic resin 20 wt %

Adipic acid mono diethyl amine salt 15 wt %

The above are thoroughly mixed at 130 degrees centigrade and then cooled to room temperature. Example 4 may be used as a solid flux which may be added to a solder paste as an activator of the paste.

When one of the carboxyls of adipic acid forms mono salt with such secondary amine, the acid dissociation constant of the other carboxyls of adipic acid is increased to increase the flux activation. Such a flux is suitable for withstanding high soldering temperatures. Therefore, even when the soldering is performed at a high temperature, for example, about 220 degrees centigrade or higher, oxidization, which reduces wettability of the solder material 110 under the lead terminals 104 of the semiconductor chip 102, can be prevented by use of the flux described above. Thus, it is possible to keep wettability of the solder material 110 even at high temperatures and an effective and beneficial back fillet 110a can be obtained at the solder joints, thereby strengthening the mechanical strength of the joints.

In one aspect of the disclosure herein, the flux may be mono salt of adipic acid and diethyl amine having the general formula of HOOC—(CH₂)ₙ—COO⁻N⁺—(CH₂CH₃)₂ (referred to herein as “ADA flux”).

As described above, presence of the ADA flux during the soldering process keeps wettability of the solder material 110, even at high soldering temperatures, so that a desirable back fillet 11 Oa is formed at the solder joint. In addition, formation of Kirkendall voids in the inter-metallic layers can be reduced by the ADA flux. Therefore, mechanical strength of the joints is strengthened.

In other aspects of the disclosure herein, the ADA flux may be used in powdered form without including rosin. By using powder ADA flux, it is easier to adjust the content thereof.

In Step S14, a solder material 110 is supplied on the soldering point between the lead terminals 104 and the solder lands 202. The plurality of lead terminals 104 are locally heated so that the solder material 110 and the flux melt to join together the lead terminals 104 and the solder lands 202.

In one aspect of the disclosure herein, the solder material 110 may be thread solder For example, the solder material 110 may be selected from F-11 (12Sn-1Ag-8Sb-79Pb, the melting point of which is about 233-243 degrees centigrade), Sn96 (Sn4.0Ag, the melting point of which is about 221 degrees centigrade), M31 (Sn-3.5Ag-0.75Cu, the melting point of which is about 217-219 degrees centigrade), Sn100C (Sn-0.65Cu0.1Ni, the melting point of which is about 227 degrees centigrade), M7O5 (Sn3.0Ag-0.5Cu, the melting point of which is about 217-219 degrees centigrade), SAC305, and the like.

In one aspect, local heating of the solder material 110 may be performed by a suitable method, such as laser irradiation, optical beam iadiation, or a soldering iron, such that heating is pin point i.e., localized at the soldering point without exposing the main body of the printed circuit board assembly 100 to the high soldering temperature. In this, the temperature applied to the solder material 110 during the local heating may be 20 to 50 degrees centigrade higher than the melting point of the solder material 110.

Local heating reduces thermal mechanical stresses on the printed circuit board assembly 100 to improve reliability thereof.

In Step S30, after the soldering process is completed, the under-fill material 120 is applied between the board 200 and the semiconductor chip 102 to fill the gap therebetween. The under-fill material 120 may be introduced by an injector. Then, the under-fill material 120 is cured in a temperature-controlled oven.

A suitable under-fill material 120 may be selected considering the thermal expansion thereof In this, an under-fill material having a thermal expansion coefficient similar to that of the semiconductor chip may be used. Further, an under-fill material having resistance to heat may be used. For example, epoxy glue under filler may be used as the under-fill material 120.

In the case of a printed circuit board assembly 100 including the semiconductor chip 102 having a plurality of fine pitch lead terminals 104, the dimensions of the connection areas between the lead terminals 104 and the board 200 are small thereby reducing mechanical strength of the solder joints between the board 200 and the semiconductor chip 102. However, even in such a case the mechanical strength reliability of the printed circuit board assembly 100 can be improved by introducing the under-fill material 120 between the board 200 and the semiconductor chip 102, even though there may be some subsequent degradation of the solder joints.

In addition, local heating of the solder material 110 may be conducted while simultaneously supplying an inert gas, such as nitrogen, argon, or the like, to the surface of the solder material (Step S16). By conducting the local heating under inert gas (for example, in one aspect the gas nitrogen) purged conditions, oxidization which reduces wettability of the solder material 110 under the lead terminals 104 of the semiconductor chip 102 can be prevented.

As discussed above, improved wettability provides for better formation of back fillets 110a. Therefore, mechanical strength of the solder joints is improved. FIG. 4 shows a cross-sectional view of the soldering point of a lead terminal 104 of the semiconductor chip 102 and a solder land 202 of the board 200 with a good back fillet 110a formed therebetween. In this, a superior and desirable back fillet 110a may have a height “F” of the solder material 110 formed under each lead terminal 104, with “F” being equal to or greater than the sum of the distance “G” between the upper surface of the solder land 202 and the lower surface of the lead terminal 104 and the thickness “T” of the lead terminal 104.

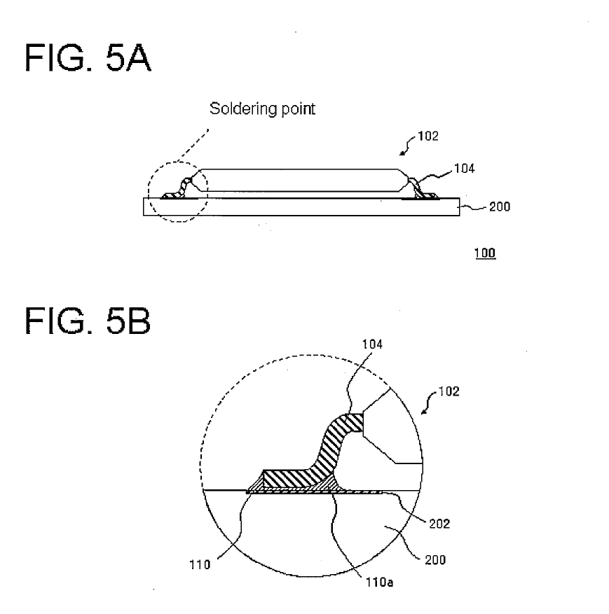

FIGS. 5A and 5B are cross-sectional views of another exemplary printed circuit board assembly 100 according to the present invention. FIG. 5B is an enlarged cross-sectional view of the soldering point of the printed circuit board assembly shown in FIG. 5A.

The printed circuit board assembly 100 shown in FIGS. 5A and 5B does not include under-fill material 120. In this case, Step S30 in FIG. 3 may be omitted.

As described above, by introducing the under-fill material 120 into the gap between the board 200 and the semiconductor chip 102, improved mechanical strength of the printed circuit board assembly 100 may be obtained thereby compensating for some degradation of the solder joints. However, by providing a suitable back fillet 110a at the solder joints, as shown in the embodiment of FIG. 4, mechanical strength of the joints can be strengthened even if the under-fill material 120 is not provided.

In one aspect of the present disclosure, the flux and the solder material 110 need not be supplied separately during the soldering process and the flux may be included in the solder material 110 and may be supplied with the solder material 110. In this, the content of the flux maybe suitably adjusted when the flux is added to the solder material 110.

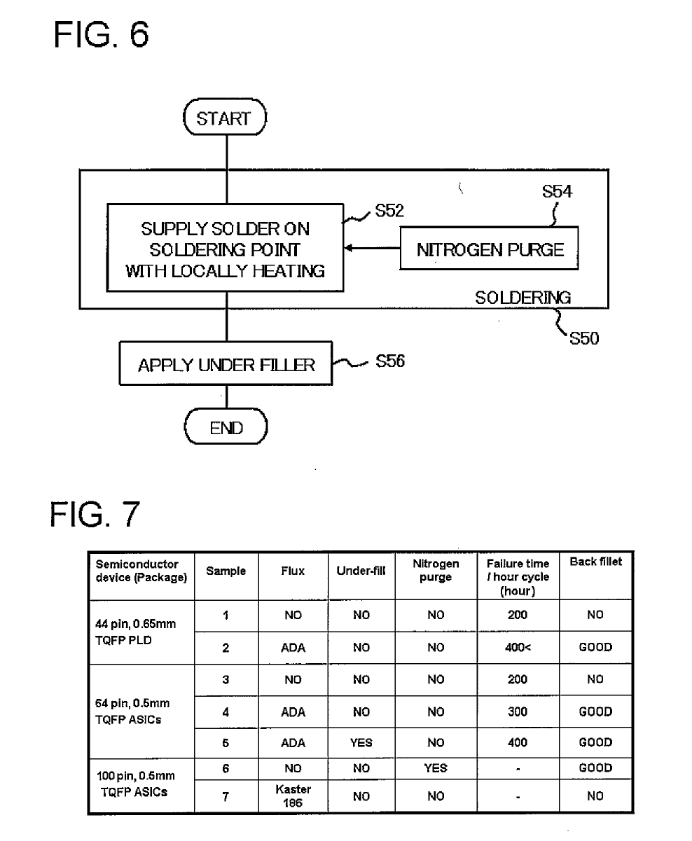

FIG. 6 is a flowchart showing another embodiment of a method of manufacturing the printed circuit board assembly 100 including soldering the semiconductor chip 102 with the board 200. In one aspect, the present embodiment does not use a flux in the soldering process.

As also described above with reference to FIG. 3, in Step S50, before the soldering process, the semiconductor chip 102 is placed on the board 200 such that the lead terminals 104 are touch with corresponding solder lands 202.

The solder material 110 is supplied on the soldering point between the lead terminals 104 and the solder lands 202. With supply of the solder material 110, the plurality of lead terminals 104 are locally heated so that the solder material 140 melts to form solder joints between each of the plurality of lead terminals 104 and each of the plurality of solder lands 202, respectively (Step S52).

In one embodiment, the local heating of the solder material 110 is conducted while supplying an inert gas, such as nitrogen, argon, or the like, to the surface of the solder material (Step S54).

By conducting the local heating under conditions wherein the soldering point is purged with a suitable inert gas (nitrogen in one embodiment), oxidization that reduces wettability of the solder material 110 under the lead terminals 104 of the semiconductor chip 102 may be prevented, even at high soldering temperatures, and a desirable back fillet at the solder joints can be obtained Therefore, mechanical strength of the joints is strengthened.

In aspects of the methods disclosed herein, the under-fill material 120 may subsequently be applied between the board 200 and the semiconductor chip 102 to fill a gap therebetween (Step S56). In this, the under-fill step may be performed as described in connection with Step S30 in FIG. 3.

As described in the preceding, the methods disclosed herein are suitable for manufacturing the printed circuit board assembly 100 shown in FIGS. 1A and 1B. In aspects of the foregoing methods, Step S56 may be omitted to obtain the printed circuit board assembly 100 shown in FIGS. 5A and 5B.

Applicants conducted testing to evaluate various printed circuit board assemblies that were manufactured according to the methods disclosed herein In the testing, a TQFP having a plurality of fine pitch lead terminals 104 was used as the semiconductor chip 102 with the flux being ADA flux. The solder material 110 used was F-11 (12Sn-1Ag-8Sb-79Pb). An epoxy under filler was used as the under-fill material 120.

Sample printed circuit board assemblies 100 were manufactured in accordance with the methods described above with the following detailed conditions. Referring to FIG. 2, the area shown by the dotted lines is one of the soldering points. The following steps were performed.

(a)Supplying the ADA flux: Powdered ADA flux was supplied on the soldering point.

(b)Soldering: Solder material was supplied on the soldering point by a temperature-controlled soldering iron at about 350 degrees centigrade. For samples using ADA flux, the solder material was supplied over the ADA flux.

(c)Under-fill: An injector was used to apply the under-fill material 120 between the board 200 and the semiconductor chip 102 to fill the gap therebetween.

(d)Nitrogen purge: For samples using a nitrogen purged environment in performing the soldering, a soldering iron capable of blowing nitrogen gas onto the soldering point was used. During the soldering, nitrogen gas was blown toward the soldering point to purge the soldering environment.

(e)Comparison: For purposes of comparison, a liquid-type flux(Rosin medium activate (RMA) type flux) was used in one of the samples.

FIG. 7 shows in a chart the manufacturing conditions and test results for the test samples.

A qualification test was performed on the test samples in which a temperature cycle between −25 degrees centigrade to 175 degrees centigrade was applied for 400 hours. Failure times are shown in FIG. 7.

Formation of back fillets were observed and the results are also shown in FIG. 7.

When the ADA flux, the under-fill, and the nitrogen purge were not used, the failure time was 200 hours for both the TQFP PLD and the TQFP ASICs (Samples 1 and 3, respectively).

When the ADA flux was applied, the failure time was extended to about 400 hours for the TQFP PLD, without using the under-fill (Sample 2). Similarly, when the ADA flux was applied, the failure time was extended to 300 hours for the TQFP ASICs, without the under-fill being used (Sample 4). When both the ADA flux and the under-fill were used, the failure time was extended to 400 hours for the TQFP ASICs (Sample 5).

Adequate back fillets, as explained above with reference to FIG. 4, were observed for Samples 2, 4, and 5. On the other hand, no back fillets were observed for Samples 1 and 3.

When nitrogen purging was used while soldering, good back fillets were observed, even without use of the ADA flux (Sample 6).

In the case of Sample 7, for which Kaster 186 was used as the flux instead of the ADA flux, no back fillets were observed.

The methods disclosed herein contemplate applications in non-fine pitch SMT ICs having gaps between IC lead terminals greater than about 0.65 mm.

The preceding description has been presented only to illustrate and describe the invention and some examples of its implementation. It is not intended to be exhaustive or to limit the invention to any precise form disclosed. Many modifications and variations are possible in light of the above teaching.

The preferred aspects were chosen and described in order to best explain the principles of the invention and its practical application. The preceding description is intended to enable others skilled in the art to best utilize the invention in various embodiments and aspects and with various modifications as are suited to the particular use contemplated. It is intended that the scope of the invention be defined by the following claims.

What is claimed is:

1. A method of manufacturing a printed circuit board assembly, comprising:
placing a semiconductor chip having a plurality of lead terminals on a board formed with a plurality of solder lands at its surface such that each of said plurality of lead terminals is in touch with a corresponding one of said plurality of solder lands;
supplying a flux comprising mono salt of adipic acid and alkyl secondary amine;
supplying a solder material at said plurality of lead terminals and said plurality of solder lands; and
locally heating said plurality of lead terminals such that said solder material and said flux are melted to join said lead terminals and said solder lands.

2. The method according to claim 1, wherein said alkyl secondary amine is diethyl amine.

3. The method according to claim 1, wherein said local heating is performed at the same time with the supply of the solder material.

4. The method according to claim 1, wherein said local heating is performed by at least one of laser irradiation, optical beam irradiation, or a soldering iron.

5. The method according to claim 1, wherein supplying a solder material comprises:
supplying the flux at said lead terminals and said solder lands; and
supplying said solder material over said flux.

6. The method according to claim 1, further comprising forming a back fillet of said solder material under each of the lead terminals.

7. The method according to claim 6, wherein said back fillet is formed such that the height “F”, from the upper surface of said solder land, of said solder material under said lead terminals is equal to or greater than the sum of the distance “G” between the upper surface of said solder land and the lower surface of said lead terminal and the thickness “T” of the lead terminal.

8. The method according to claim 1, further comprising supplying, after said local heating, an under-fill material between said board and said semiconductor chip to fill a gap therebetween.

9. The method according to claim 1, wherein the melting point of said solder material is equal to or greater than 200 degrees centigrade.

10. The method according to claim 1, further comprising supplying an inert gas to the surface of said solder material during said local healing.

11. The method according to claim 1, further comprising, after said local heating, supplying an under-fill material between said board and said semiconductor chip to fill a gap therebetween, wherein
said alkyl secondary amine is diethyl amine, and
the melting point of said solder material is equal to or greater than 200 degrees centigrade.

12. A method of manufacturing a printed circuit board assembly, comprising:
placing a semiconductor chip having a plurality of lead terminals on a board formed with a plurality of solder lands at its surface such that each of said plurality of lead terminals is in touch with a corresponding one of said plurality of solder lands;
supplying a solder material on said plurality of lead terminals and said plurality of solder lands;
locally heating said plurality of lead terminals such that said solder material is melted to join said plurality of lead terminals and said plurality of solder lands; and
supplying an inert gas to the surface of said solder material during said local heating.

13. The method according to claim 12, further comprising, after said local heating, supplying an under-fill material between said board and said semiconductor chip to fill a gap therebetween.

14. The method according to claim 12, wherein the melting point of said solder material is equal to or greater than 200 degrees centigrade.

15. The method according to claim 12, further comprising forming a back fillet under the lead terminals.

16. The method according to claim 15, wherein said back fillet is formed such that the height “F”, from the upper surface of said solder land, of said solder material formed under said lead terminals is equal to or greater than the sum of the distance “G” between the upper surface of said solder land and the lower surface of said lead terminal and the thickness “T” of the lead terminal.

17. The method according to claim 12, wherein said local heating is performed at the same time with supplying said solder material.

18. The method according to claim 12, wherein said local heating is performed by at least one of laser irradiation, optical beam irradiation, or a soldering iron.

19. The method according to claim 12, further comprising supplying, after said local heating, an under-fill material between said board and said semiconductor chip to fill a gap therebetween, wherein the melting point of said solder material is equal to or greater than 200 degrees centigrade.
